(19) United States
(12) Patent Application Publication
(10) Pub. No.: US 2022/0005883 A1
(43) Pub. Date: Jan. 6, 2022

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Feng ZHANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/652,794

(22) PCT Filed: Jan. 7, 2020
(86) PCT No.: PCT/CN2020/070749

§ 371 Date: Apr. 1, 2020

(30) Foreign Application Priority Data
Oct. 28, 2019 (CN) 201911029303.5

(51) Int. Cl. H01L 27/32

(52) U.S. Cl. CPC H01L 27/3218; H01L 27/3234; H01L 27/3232

(57) ABSTRACT

A display panel and a display device are provided. The display panel includes a display area including a light transmission area and a main display area surrounding the light transmission area. In the light transmission area, the display panel includes an integrated optical fiber layer including a plurality of optical fibers, and each optical fiber includes a light-entering end and a light-exiting end. Light enters from the light-entering end of the optical fiber, and is reflected to the light-exiting end of the optical fiber through an interior of the optical fiber.

### CROSS REFERENCE TO RELATED APPLICATIONS

This application claims the priority of a Chinese Patent Application No. 201911029303.5, filed on Oct. 28, 2019, titled “DISPLAY PANEL AND DISPLAY DEVICE”, the entire contents of which are incorporated herein by reference.

### FIELD OF DISCLOSURE

The present disclosure relates to the field of display panel technologies, and in particular, to a display panel and a display device.

### BACKGROUND

As a new display technology, organic light-emitting diodes (OLEDs) have many unparalleled advantages in other display technologies, such as wide viewing angles, high contrast, fast response times, low power consumption, and foldability, so they have strong competitiveness in a next generation of displays.

With a widespread development and in-depth application of the OLED technology, a pursuit of high screen-to-body ratio with better visual experience and a pursuit of full-screen display panels have become one of current trends in a display technology development. Under-screen fingerprint recognition technologies, under-screen sensing technologies, and O-Cut technologies, etc., have greatly increased a screen-to-body ratio of the display. However, a camera under panel (CUP) technology still faces many constraints such as structural design.

If a camera module is below a screen, there are some low-transmittance film layers (such as PI) and opaque metal traces (such as GE, SD, and anode) in a substrate of the screen. It will seriously weaken a transmittance of external light and produce a significant “screen door effect”, which will affect a performance of the camera under the screen on an image acquisition. In order to ensure that the camera module can receive more light, a diameter of a light transmission area in the panel is also larger, which leads to the goal of not achieving a screen-to-body ratio.

Therefore, it is necessary to develop a new type of display panel to overcome the defects of the existing technology.

### SUMMARY OF DISCLOSURE

An object of the present disclosure is to provide a display panel, which can solve the problems of small transmittance of the panel and excessively large opening diameter in the prior art.

In order to achieve the above object, the present disclosure provides a display panel, including a display area including a light transmission area and a main display area surrounding the light transmission area. In the light transmission area, the display panel includes an integrated optical fiber layer including a plurality of optical fibers, and each optical fiber includes a light-entering end and a light-exiting end. Light enters from the light-entering end of the optical fiber, and is reflected to the light-exiting end of the optical fiber through an interior of the optical fiber.

Furthermore, in other embodiments, the display panel further includes an array substrate and a luminous layer. The array substrate includes a plurality of sub-pixels arranged in an array. The luminous layer is disposed on the array substrate. In the light transmission area, the integrated optical fiber layer is disposed below the array substrate, and the light-entering end of each optical fiber is connected below the array substrate.

Furthermore, in other embodiments, the luminous layer includes a plurality of luminous units arranged in an array, there is a gap between two adjacent luminous units, and the light enters the light-entering end of the optical fiber through the gap.

Furthermore, in other embodiments, the optical fibers have the same diameter or different diameters.

Furthermore, in other embodiments, in response to the optical fibers having the same diameter, the diameter of each optical fiber ranges from 2 μm to 3 μm.

Furthermore, in other embodiments, in response to different diameters of the optical fibers, the diameter of each optical fiber ranges from 1 μm to 3 μm.

Furthermore, in other embodiments, a distribution density of the luminous units in the light transmission area is equal to a distribution density of the luminous units in the main display area; or each luminous unit corresponds to one sub-pixel, and a distribution density of the sub-pixels in the light transmission area is equal to a distribution density of the sub-pixels in the main display area.

Furthermore, in other embodiments, a distribution density of the luminous units in the light transmission area is less than a distribution density of the luminous units in the main display area; or each luminous unit corresponds to one sub-pixel, and a distribution density of the sub-pixels in the light transmission area is less than a distribution density of the sub-pixels in the main display area.

Furthermore, in other embodiments, a thickness of the integrated optical fiber layer ranges from 20 μm to 30 μm.

Furthermore, in other embodiments, a thin film encapsulation layer is disposed on the luminous layer.

Another object of the present disclosure is to provide a display device including the display panel as described in the present disclosure and a camera. The camera is disposed below the light transmission area of the display panel or disposed in an area other than below the light transmission area of the display panel, and the light-exiting end of the optical fiber is connected to the camera.

In comparison with the prior art, advantages of the present disclosure are as follow. The present disclosure provides the display panel and the display device, and uses a total reflection characteristic of the optical fibers to integrate the plurality of optical fibers into the optical fiber layer which is connected to the camera and the array substrate under the screen. External light can enter the light-entering end of the optical fiber through the gap of the sub-pixels, and then be reflected by the interior of the optical fiber to the light-exiting end of the optical fiber, and finally reflected to the camera under the screen. Therefore, it can not only affect a normal luminous efficiency of the light transmission area, but also effectively improve an extraction efficiency of the external light by the camera under the screen, thereby avoiding a “screen door effect”. In addition, it can reduce the diameter of the light transmission area, achieve a purpose of high screen-to-body ratio, and realize a true full screen technology.

### BRIEF DESCRIPTION OF DRAWINGS

In order to explain technical solutions in embodiments of the present disclosure more clearly, drawings used in the description of the embodiments will be briefly introduced below. Apparently, the drawings in the following description are just some embodiments of the present disclosure. For those skilled in the art, other drawings can be obtained based on these drawings without creative efforts.

FIG. 1 is a cross-sectional view of a display panel of a first embodiment of the present disclosure.

FIG. 2 is a top view of the display panel of the first embodiment of the present disclosure.

FIG. 3 is a cross-sectional view of a display device of the first embodiment of the present disclosure.

FIG. 4 is a cross-sectional view of a display panel of a second embodiment of the present disclosure.

FIG. 5 is a top view of the display panel of the second embodiment of the present disclosure.

FIG. 6 is a top view of the display panel of a third embodiment of the present disclosure.

### REFERENCE NUMERALS

display panel 10; display device 20;
display area 100; main display area 101; light transmission area 102;
array substrate 1; sub-pixel 11;
luminous layer 2; luminous unit 21;
integrated optical fiber layer 3; optical fiber 31;
light-entering end 311; light-exiting end 312;
thin film encapsulation layer 4;
camera 5

### DETAILED DESCRIPTION

To make the objectives, technical solutions, and advantages of the embodiments of the present disclosure clearer, the technical solutions according to the embodiments of the present disclosure are clearly and completely described in the following with reference to the accompanying drawings in the embodiments of the present disclosure. Apparently, the embodiments in the following description are a part of the embodiments rather than all of the embodiments of the present disclosure. All other embodiments obtained by persons of ordinary skill in the art based on the embodiments of the present disclosure without making creative efforts shall fall within the protection scope of the present disclosure.

It should be mentioned that the specific structural and functional details disclosed herein are merely illustrative and are for the purpose of describing the exemplary embodiments of the present disclosure. However, the disclosure may be embodied in many alternate forms and should not be construed as limited only to the embodiments set forth herein.

### First Embodiment

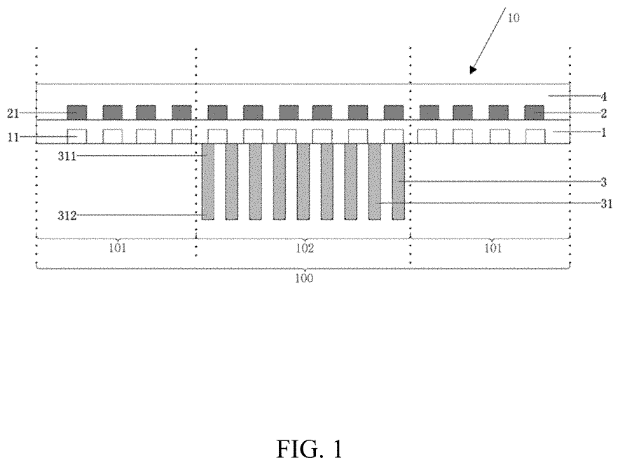

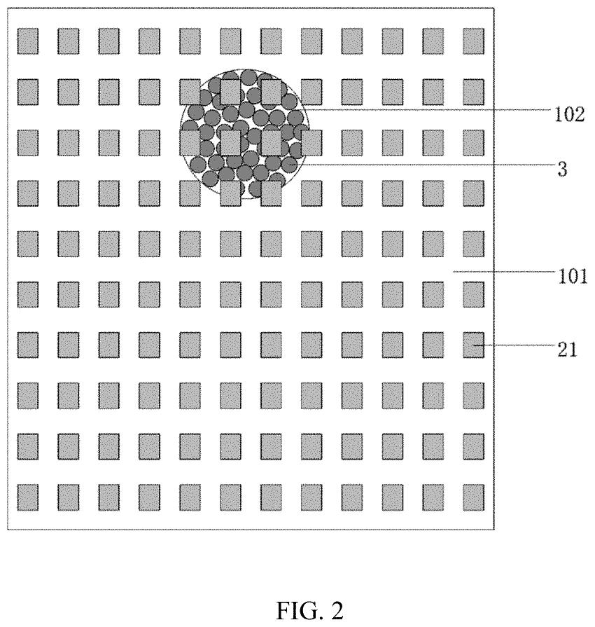

Please refer to FIG. 1 and FIG. 2. FIG. 1 is a cross-sectional view of a display panel of a first embodiment of the present disclosure. FIG. 2 is a top view of the display panel of the first embodiment of the present disclosure. This embodiment provides a display panel 10 including a display area 100. The display area includes a light transmission area 102 and a main display area 101 surrounding the light transmission area 102.

The display panel includes an array substrate 1, a luminous layer 2 disposed on the array substrate 1, and a thin film encapsulation layer 4 disposed on the luminous layer 2.

The array substrate 1 includes a plurality of sub-pixels 11 arranged in an array, and there is a gap between two adjacent sub-pixels 11.

In this embodiment, a distribution density of sub-pixels 11 in the main display area 101 is the same as a distribution density of sub-pixels 11 in the light transmission area 102.

Specifically, the array substrate 1 includes a substrate, a buffer layer, an active layer, a gate insulating layer, a gate layer, a source/drain layer, a planarization layer, and a pixel electrode layer. The buffer layer is disposed on the substrate. The active layer is disposed on the buffer layer. The gate insulating layer is disposed on the active layer. The gate layer is disposed on the gate insulating layer. The source/drain layer is disposed on the gate layer. The planarization layer is disposed on the source/drain layer. The pixel electrode layer is disposed on the planarization layer. The array substrate 1 includes the plurality of sub-pixels 11 arranged in an array, and each sub-pixel includes the active layer, the gate insulating layer, the gate layer, and the source/drain layer. A design point of the present disclosure lies in the integrated optical fiber layer 3 disposed below the array substrate 1, so a detailed structure of the array substrate 1 will not be described one by one.

The luminous layer 2 includes a plurality of luminous units 21 arranged in an array. There is a gap between two adjacent luminous units 21. Each sub-pixel 11 corresponds to a luminous unit 21. A distribution density of luminous units 21 in the main display area 101 is the same as a distribution density of luminous units 21 in the light transmission area 102. Alternatively, a distribution density of sub-pixels 11 in the light transmission area 102 is equal to a distribution density of sub-pixels 11 in the main display area 101. The luminous unit 21 includes a blue luminous unit, a red luminous unit, and a green luminous unit.

The integrated optical fiber layer 3 is disposed below the light transmission area 102 and the array substrate 1. The integrated optical fiber layer 3 includes a plurality of optical fibers 31. Each optical fiber 31 includes a light-entering end 311 and a light-exiting end 312. The light-entering end 311 is connected below the array substrate 1.

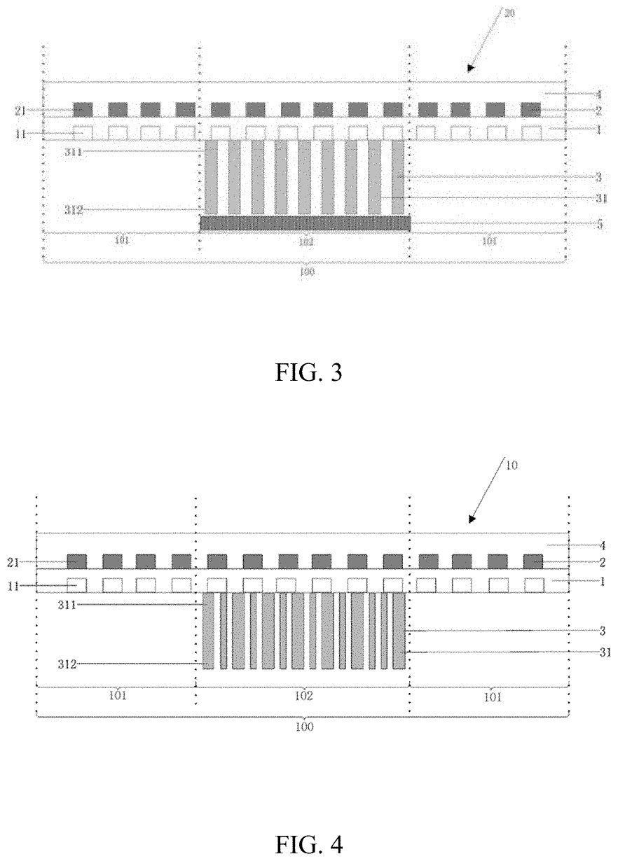

Please refer to FIG. 3, this embodiment also provides a display device. FIG. 3 is a cross-sectional view of a display device of the first embodiment of the present disclosure. The display device 20 includes the display panel 10 according to this first embodiment and a camera 5. The camera 5 is disposed below the light transmission area 102 of the display panel or disposed in an area other than below the light transmission area 102 of the display panel.

The integrated optical fiber layer 3 is disposed below the array substrate 1. The integrated optical fiber layer 3 includes the plurality of optical fibers 31. Each optical fiber 31 includes the light-entering end 311 and the light-exiting end 312. The light-entering end 311 is connected below the array substrate 1. The luminous layer 2 includes the plurality of luminous units 21 arranged in an array. Each sub-pixel 11 corresponds to one luminous unit 21. The distribution density of the luminous units 21 in the main display area 101 is the same as the distribution density of the luminous unit 11 in the light transmission area 102. External light enters the light-entering end of the optical fiber 31 through the gap between the luminous units 21. The light-entering end 311 of the optical fiber 31 is connected to the array substrate 1. The light-exiting end 312 of the optical fiber 31 is connected to the camera 5.

The optical fiber 31 has total reflection characteristics. External light can enter the light-entering end 311 of the optical fiber 31 through the gap of the luminous units 21, and then be reflected by the interior of the optical fiber 31 to the light-exiting end 312 of the optical fiber, and finally reflected to the camera 5 under the screen. Therefore, it can not only affect a normal luminous efficiency of the light transmission area 102, but also effectively improve an extraction efficiency of the external light by the camera under the screen, thereby avoiding a “screen door effect”. In addition, it can reduce a diameter of the light transmission area, achieve a purpose of high screen-to-body ratio, and realize a true full screen technology.

In this embodiment, the optical fibers 31 have the same diameter. The diameter of the optical fiber 31 ranges from 2 μm to 3 μm. A process of the optical fibers with the same diameter is simple and can save costs. In order to increase the light transmittance, an area formed by the light-entering ends 311 of all optical fibers 31 is infinitely close to an area of the light transmission area 102. In this embodiment, the area formed by the light-entering ends 311 of all the optical fibers 31 accounts for more than 90% of the area of the light transmission area 102.

The light transmission area 102 includes the integrated optical fiber layer 3, the array substrate 1, the luminous layer 2, and the thin film encapsulation layer 4 arranged in this order. The transmittance of these layers is greater than 90%.

### Second Embodiment

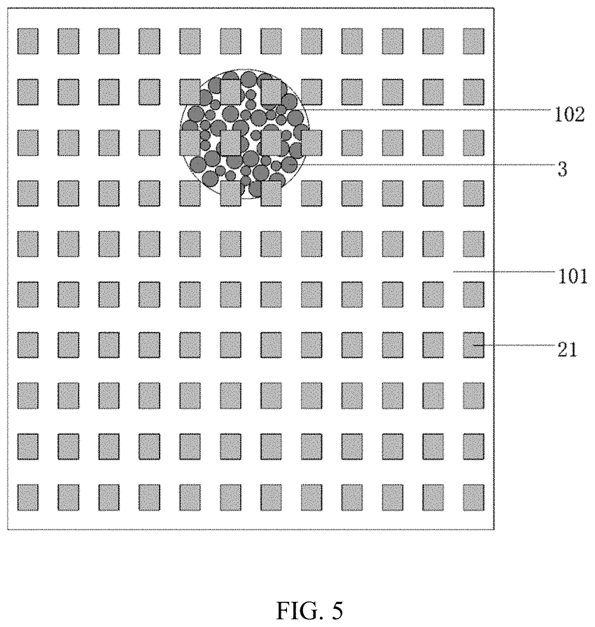

Please refer to FIG. 4 and FIG. 5. FIG. 4 is a cross-sectional view of a display panel of a second embodiment of the present disclosure. FIG. 5 is a top view of the display panel of the second embodiment of the present disclosure. A structure of the display panel in this embodiment is roughly the same as that of the first embodiment. An integrated optical fiber layer 3 is also disposed below an array substrate 1. The integrated optical fiber layer 3 includes a plurality of optical fibers 31. Each optical fiber 31 includes a light-entering end 311 and a light-exiting end 312. The light-entering end 311 is connected below the array substrate 1. A luminous layer 2 includes a plurality of luminous units 21 arranged in an array. Each sub-pixel 11 corresponds to one luminous unit 21. A distribution density of the luminous units 21 in the main display area 101 is the same as a distribution density of the luminous units 21 in the light transmission area 102. External light enters the light-entering end of the optical fiber 31 through a gap between luminous units 21. For the same structure, please refer to the above, and it will not be repeated here. The main difference is that a diameter of the optical fiber 31 is different, and the diameter of the optical fiber ranges from 1 μm to 3 μm.

In order to increase a light transmittance of the light transmission area 102, an area formed by the light-entering ends 311 of all optical fibers 31 is infinitely close to an area of the light transmission area 102. In this embodiment, the area formed by the light-entering ends 311 of all the optical fibers 31 accounts for more than 90% of the area of the light transmission area 102.

In this embodiment, the diameters of the optical fibers 31 are different, so that a ratio of the area occupied by the optical fibers 31 in the light transmission area 102 can be increased. Through the gap of luminous units 21, the extraction efficiency of external light is further improved. Therefore, it can not only affect a normal luminous efficiency of the light transmission area, but also effectively improve an extraction efficiency of the external light by the camera under the screen, thereby avoiding a “screen door effect”. In addition, it can reduce the diameter of the light transmission area, achieve a purpose of high screen-to-body ratio, and realize a true full screen technology.

### Third Embodiment

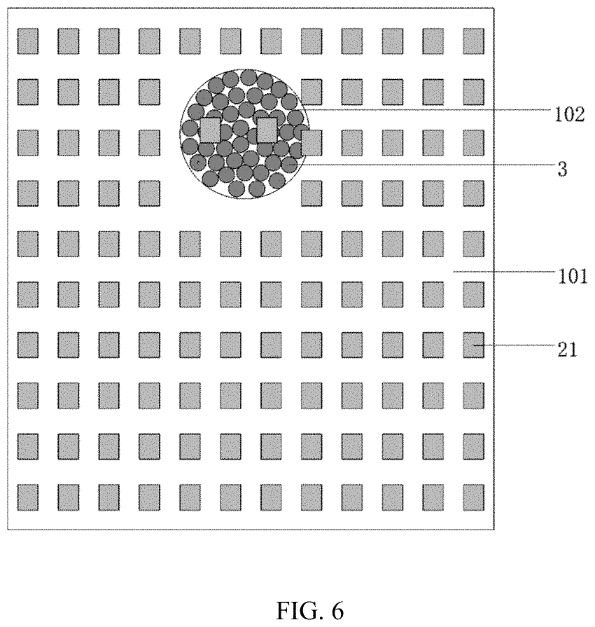

Please refer to FIG. 6, which is a top view of the display panel of a third embodiment of the present disclosure. A structure of the display panel in this embodiment is roughly the same as that of the first embodiment. An integrated optical fiber layer 3 is also disposed below an array substrate 1. The integrated optical fiber layer 3 includes a plurality of optical fibers 31. Each optical fiber 31 includes a light-entering end 311 and a light-exiting end 312. The light-entering end 311 is connected below the array substrate 1. A luminous layer 2 includes a plurality of luminous units 21 arranged in an array. Each sub-pixel 11 corresponds to one luminous unit 21. External light enters the light-entering end of the optical fiber 31 through a gap between luminous units 21. For the same structure, please refer to the above, and it will not be repeated here. The main difference is that a distribution density of the luminous units 21 in the light transmission area 102 is less than a distribution density of the luminous units 21 in the main display area 101; or a distribution density of the sub-pixels 11 in the light transmission area 102 is less than a distribution density of the sub-pixels 11 in the main display area 101.

In order to increase a light transmittance of the light transmission area 102, an area formed by the light-entering ends 311 of all optical fibers 31 is infinitely close to an area of the light transmission area 102. In this embodiment, the area formed by the light-entering ends 311 of all the optical fibers 31 accounts for more than 90% of the area of the light transmission area 102.

In this embodiment, by reducing the density of the luminous units 21 in the light transmission area 102, the ratio of the area occupied by the optical fibers 31 through the gap of the luminous units 21 is increased. That is, an extraction efficiency of the external light by the optical fibers 31 is effectively improved, thereby avoiding a “screen door effect”. In addition, it can reduce the diameter of the light transmission area, achieve a purpose of high screen-to-body ratio, and realize a true full screen technology.

Advantages of the present disclosure are as follow. The present disclosure provides the display panel and the display device, and uses a total reflection characteristic of the optical fibers to integrate the plurality of optical fibers into the optical fiber layer which is connected to the camera and the array substrate under the screen. External light can enter the light-entering end of the optical fiber through the gap of the sub-pixels, and then be reflected by the interior of the optical fiber to the light-exiting end of the optical fiber, and finally reflected to the camera under the screen. Therefore, it can not only affect a normal luminous efficiency of the light transmission area, but also effectively improve an extraction efficiency of the external light by the camera under the screen, thereby avoiding a “screen door effect”. In addition, it can reduce the diameter of the light transmission area, achieve a purpose of high screen-to-body ratio, and realize a true full screen technology.

The above is only preferred embodiments of the present disclosure. It should be noted that, for those of ordinary skill in the art, without departing from the principles of the present disclosure, several improvements and modifications can be made, and these improvements and modifications should also be regarded as the protection scope of the present disclosure.

What is claimed is:

1. A display panel, comprising a display area comprising a light transmission area and a main display area surrounding the light transmission area, wherein in the light transmission area, the display panel comprises an integrated optical fiber layer comprising a plurality of optical fibers, and each optical fiber comprises a light-entering end and a light-exiting end; and
wherein light enters from the light-entering end of the optical fiber, and is reflected to the light-exiting end of the optical fiber through an interior of the optical fiber.

2. The display panel as claimed in claim 1, further comprising:
an array substrate comprising a plurality of sub-pixels arranged in an array; and
a luminous layer disposed on the array substrate, wherein in the light transmission area, the integrated optical fiber layer is disposed below the array substrate, and the light-entering end of each optical fiber is connected below the array substrate.

3. The display panel as claimed in claim 1, wherein the luminous layer comprises a plurality of luminous units arranged in an array, there is a gap between two adjacent luminous units, and the light enters the light-entering end of the optical fiber through the gap.

4. The display panel as claimed in claim 1, wherein the optical fibers have the same diameter or different diameters.

5. The display panel as claimed in claim 4, wherein in response to the optical fibers having the same diameter, the diameter of each optical fiber ranges from 2 μm to 3 μm.

6. The display panel as claimed in claim 4, wherein in response to different diameters of the optical fibers, the diameter of each optical fiber ranges from 1 μm to 3 μm.

7. The display panel as claimed in claim 1, wherein a distribution density of the luminous units in the light transmission area is equal to a distribution density of the luminous units in the main display area; or
each luminous unit corresponds to one sub-pixel, and a distribution density of the sub-pixels in the light transmission area is equal to a distribution density of the sub-pixels in the main display area.

8. The display panel as claimed in claim 1, wherein a distribution density of the luminous units in the light transmission area is less than a distribution density of the luminous units in the main display area; or
each luminous unit corresponds to one sub-pixel, and a distribution density of the sub-pixels in the light transmission area is less than a distribution density of the sub-pixels in the main display area.

9. The display panel as claimed in claim 1, wherein a thickness of the integrated optical fiber layer ranges from 20 μm to 30 μm.

10. A display device, comprising the display panel as claimed in claim 1 and a camera, wherein the camera is disposed below the light transmission area of the display panel or disposed in an area other than below the light transmission area of the display panel, and the light-exiting end of the optical fiber is connected to the camera.

11. The display device as claimed in claim 10, further comprising:
an array substrate comprising a plurality of sub-pixels arranged in an array; and
a luminous layer disposed on the array substrate, wherein in the light transmission area, the integrated optical fiber layer is disposed below the array substrate, and the light-entering end of each optical fiber is connected below the array substrate.

12. The display device as claimed in claim 10, wherein the luminous layer comprises a plurality of luminous units arranged in an array, there is a gap between two adjacent luminous units, and the light enters the light-entering end of the optical fiber through the gap.

13. The display device as claimed in claim 10, wherein the optical fibers have the same diameter or different diameters.

14. The display device as claimed in claim 13, wherein in response to the optical fibers having the same diameter, the diameter of each optical fiber ranges from 2 μm to 3 μm.

15. The display device as claimed in claim 13, wherein in response to different diameters of the optical fibers, the diameter of each optical fiber ranges from 1 μm to 3 μm.

16. The display device as claimed in claim 10, wherein a distribution density of the luminous units in the light transmission area is equal to a distribution density of the luminous units in the main display area; or
each luminous unit corresponds to one sub-pixel, and a distribution density of the sub-pixels in the light transmission area is equal to a distribution density of the sub-pixels in the main display area.

17. The display device as claimed in claim 10, wherein a distribution density of the luminous units in the light transmission area is less than a distribution density of the luminous units in the main display area; or
each luminous unit corresponds to one sub-pixel, and a distribution density of the sub-pixels in the light transmission area is less than a distribution density of the sub-pixels in the main display area.

18. The display device as claimed in claim 10, wherein a thickness of the integrated optical fiber layer ranges from 20 μm to 30 μm.
